(19) United States
(12) Patent Application Publication
(10) Pub. No.: US 2009/0277000 A1
(43) Pub. Date: Nov. 12, 2009

(54) MANUFACTURING APPARATUS OF STORAGE UNIT

(75) Inventor: Shigeyuki Kotake, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/506,850

(22) Filed: Jul. 21, 2009

Related U.S. Application Data
(63) Continuation of application No. PCT/JP2007/051637, filed on Jan. 31, 2007.

(51) Int. Cl. H05K 13/00

(52) U.S. Cl. 29/729

(57) ABSTRACT

A manufacturing apparatus configured to manufacture a storage unit by mounting an object onto a spindle motor that is attached to a housing and configured to rotate the object includes a centering mechanism that includes a first centering unit engaged with a spindle hub of the spindle motor and configured to center the spindle hub, and a second centering unit provided concentric to the first centering part and configured to center the object, and an attachment unit configured to attach the object around the spindle hub while the centering mechanism aligns a center of the spindle hub with a center of the object.

This application is a continuation based on International Application No. PCT/JP2007/051637.

### BACKGROUND OF THE INVENTION

1. Field of the Invention

The present invention relates generally to a manufacturing apparatus of a storage unit, and more particularly to a manufacturing apparatus configured to manufacture a storage unit by mounting a recording medium onto a housing. The present invention is suitable, for example, for an automatic mounting apparatus configured to mount a plurality of disks and one or more spacers around a (spindle) hub attached to a disk enclosure (“DE”) of a hard disk drive (“HDD”).

2. Description of the Related Art

It has recently been increasingly required to provide a sophisticated and large-capacity HDD with good productivity. The typical HDD includes a plurality of disks, one or more spacers configured to space the disks, a spindle motor configured to rotate the disks, and a slider configured to support a head and to float above the corresponding disk.

In order to improve the productivity, an automatic mounting apparatus is conventionally used which mounts the disks and the spacer(s) around the hub of the spindle motor that has been previously attached to the DE as a housing. The DE is carried to a mounting position by a moving unit. When the DE reaches the mounting position, the automatic mounting apparatus sequentially layers the disks and the spacer(s) while it fixes the DE at the mounting position. At that time, the subsequent DE waits in front of the mounting position while it is made idle relative to the moving unit. This idling is referred to free flow.

Any dusts in the HDD would degrade the performance, such as a failure of recording or reproducing by the head, low positioning precision of the head, or collisions between the slider and the dusts. Thus, the dustproof characteristic of the HDD is important, and the automatic mounting apparatus mounts the disks and the spacer onto the DE in a clean room environment so as to improve the dustproof characteristic. Moreover, the spacers are cleansed by the cleansing apparatus outside of the clean room before mounting, and an operator manually mounts the cleansed spacers to a cassette or jig and then manually mounts the cassette onto the automatic mounting apparatus.

The demand for the dustproof characteristic of the HDD becomes increasingly stricter as a recording density of the disk becomes higher, and the automatic mounting apparatus is demanded to further restrain generations of the dusts. As a result of investigations of dust sources at the mounting time by the automatic mounting apparatus, the instant inventor has discovered that 1) the dust may occur when the disk or the spacer rubs the side surface of the spindle hub of the spindle motor and one of them is scraped; 2) the dust may adhere to the spacer when the spacer is manually moved from the cleansing apparatus to the cassette; and 3) the dust may occur due to the frictions between the moving unit and the DE in the free flow state.

### SUMMARY OF THE INVENTION

The present invention provides a manufacturing apparatus configured to manufacture a highly dustproof disk drive with good productivity.

A manufacturing apparatus according to one aspect of the present invention is configured to manufacture a storage unit by mounting an object onto a spindle motor that is attached to a housing and configured to rotate the object. The manufacturing apparatus includes a centering mechanism that includes a first centering unit configured to be engaged with a spindle hub of the spindle motor and to center the spindle hub, and a second centering unit provided concentric to the first centering part and configured to center the object, and an attachment unit configured to attach the object around the spindle hub while said centering mechanism accords a center of the spindle hub with a center of the object. According to this manufacturing apparatus, while the centering mechanism accords the center of the spindle hub with the center of the object, the object is attached to around the spindle hub. Since the alignment between the spindle hub and the object has been completed, the object can be mounted without rubbing the side surface of the spindle hub, restraining or preventing generations of the dusts.

The object may include at least two disks each serving as a recording medium, and a spacer provided between the disks and configured to space the disks, and the manufacturing apparatus may include at least three centering mechanisms and at least three attachment units corresponding to the two disks and the spacer. By providing each object with a different centering mechanism, the dust generation amount can be reduced relative to each object. The manufacturing apparatus may further include three stations arranged at different positions in parallel, and each station may include a pair of corresponding centering mechanism and attachment unit, and a moving unit configured to move the housing and to stop the housing when the housing is located at a mounting position. By stopping the moving unit in attaching each object, the dust that would otherwise occur due to the free flow can be restrained. In addition, the parallel processing can improve the productivity.

The manufacturing apparatus may further include a spacer cassette that includes a support configured to support the spacer so that the spacer can be taken out, the spacer cassette may expose the spacer at part other than part where the support contacts the spacer, the spacer cassette being configured to commonly mounted on the manufacturing apparatus and a cleansing apparatus configured to cleanse the spacer. When the spacer cassette is configured to be mounted commonly onto the cleansing apparatus and the manufacturing apparatus and configured to expose the spacer, the spacer can be cleansed with the cassette. Since a transfer of the spacer from the cleansing apparatus to the cassette becomes unnecessary unlike the prior art, the dust that would otherwise occur due to the transfer can be restrained. The support may include three cylinders used to hold the spacer, and each cylinder may have a plurality of annular grooves arranged at regular intervals in a longitudinal direction, the spacer being engaged with each annular groove. This structure enables the adjacent spacers to be held without collisions in cleansing, such as the ultrasonic cleansing time, and the drainage in drying improves. The spacer cassette is made of a durable material, such as stainless steel.

Further features of the present invention will become apparent from the following description of exemplary embodiments with reference to the attached drawings.

### BRIEF DESCRIPTION OF THE DRAWINGS

FIG. 1 is a perspective overview of an automatic mounting apparatus according to one aspect of the present invention, from which a case is detached.

FIG. 2 is a perspective overview of the automatic mounting apparatus shown in FIG. 1, to which the case is attached.

FIG. 3 is a sectional view of a DE mounted with two disks and one spacer by the automatic mounting apparatus shown in FIG. 2.

FIG. 4 is a perspective overview of the DE shown in FIG. 3.

FIG. 5 is a partially enlarged and transparent perspective view of the automatic mounting apparatus shown in FIG. 1.

FIG. 6 is a partially enlarged perspective view of the centering mechanism shown in FIG. 5.

FIG. 7 is a partially enlarged plane view of the centering mechanism shown in FIG. 6.

FIG. 8 is a partially enlarged, sectional and perspective view of the centering mechanism shown in FIG. 6.

FIG. 9 is a partially enlarged sectional view of the centering mechanism shown in FIG. 6.

FIG. 10 is a partially enlarged perspective view of a transporting mechanism shown in FIG. 1.

FIG. 11 is a schematic perspective view near a spacer cassette shown in FIG. 1.

FIG. 12 is an enlarged perspective view of the spacer cassette shown in FIG. 11 that is mounted with no spacers.

FIG. 13 is an enlarged perspective view of the spacer cassette shown in FIG. 11 mounted with the spacers.

FIG. 14 is a block diagram of a control system of the automatic apparatus shown in FIG. 1.

FIG. 15 is a schematic perspective view for explaining that the automatic mounting apparatus shown in FIG. 1 mounts a first disk.

FIG. 16 is a schematic perspective view for explaining that the automatic mounting apparatus shown in FIG. 1 mounts the first disk.

FIG. 17 is a schematic perspective view for explaining that the automatic mounting apparatus shown in FIG. 1 mounts the first disk.

FIG. 18 is a schematic perspective view for explaining that the automatic mounting apparatus shown in FIG. 1 mounts the first disk.

FIG. 19 is a schematic perspective view for explaining that the automatic mounting apparatus shown in FIG. 1 mounts the first disk.

FIG. 20 is a schematic perspective view for explaining that the automatic mounting apparatus shown in FIG. 1 mounts the first disk.

FIG. 21 is a schematic perspective view for explaining that the automatic mounting apparatus shown in FIG. 1 mounts a spacer.

FIG. 22 is a schematic perspective view for explaining that the automatic mounting apparatus shown in FIG. 1 mounts the spacer.

FIG. 23 is a schematic perspective view for explaining that the automatic mounting apparatus shown in FIG. 1 mounts the spacer.

FIG. 24 is a schematic perspective view for explaining that the automatic mounting apparatus shown in FIG. 1 mounts the spacer.

### DESCRIPTION OF THE EMBODIMENTS

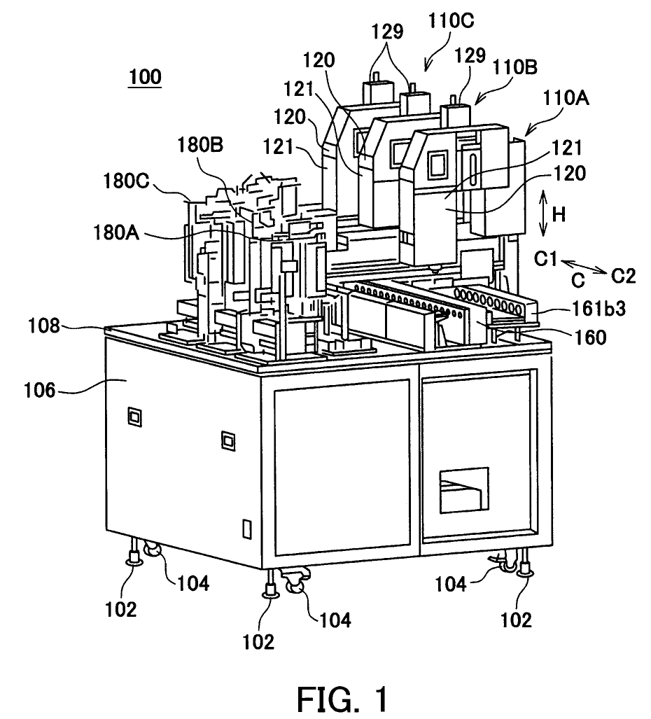

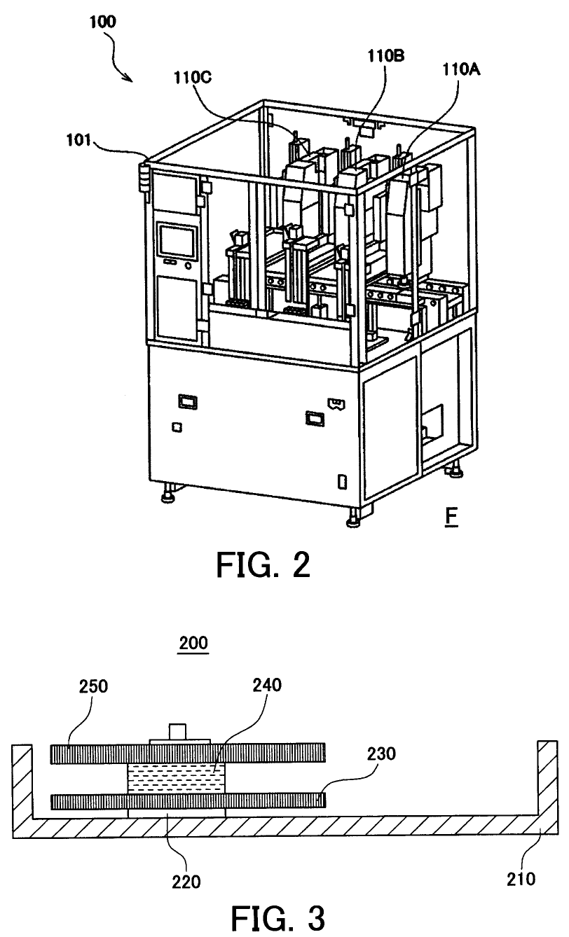

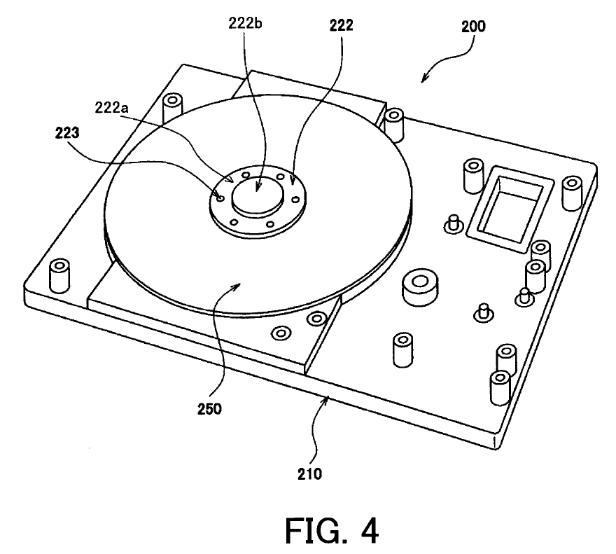

Referring now to the accompanying drawings, a description will be given of an automatic mounting apparatus (HDD manufacturing apparatus) 100 according to one embodiment of the present invention. FIG. 1 is a perspective overview of the automatic mounting apparatus 100, from which a case 101 is detached. FIG. 2 is a perspective overview of the automatic mounting apparatus 100, to which the case 101 is attached. FIG. 3 is a schematic sectional view of an (unfinished) HDD 200 mounted with two disks 230 and 250 and one spacer 240 by the automatic mounting apparatus 100. FIG. 4 is a perspective overview of the HDD 200.

As shown in FIGS. 3 and 4, the automatic mounting apparatus 100 is an apparatus configured to automatically mount the disks 230 and 250 and the spacer 240 around a hub 222 of a spindle motor 220 that has been previously attached to a DE 210 of the HDD 200. The disk 230, the spacer 240, and the disk 250 are mounted in this order, but the number of disks and the number of spacers are not limited. After the automatic mounting apparatus 100 completes mounting, a post process follows, such as attachments of a clamp ring and a head stack assembly (not shown) to the HDD 200.

The DE is a rectangular parallelepiped housing, for example, made from aluminum die casting or made of stainless steel.

The spindle motor 220 includes, for example, a brushless DC motor (not shown), and a (spindle) hub 222 as a rotator. The hub 222 is shaped by concentrically arranging two cylinders, and includes an outer cylinder 222a and an inner cylinder 222b. The outer cylinder 222a has an annular shape when viewed from the top, and six screw holes 223 arranged at regular intervals used to attach the clamp ring onto the hub 222. The number of screw holes 223 is not limited. The inner cylinder 222b is a convex that projects from the outer cylinder 222a, and is a part with which the inner centering part 134 is engaged, as will be described later.

Each of the disks 230 and 250 has a high surface recording density, such as 100 Gb/in². It is particularly important to improve the dustproof characteristic for the HDD 200 that has a disk with a high surface recording density. The disks 230 and 250 and the spacer 240 are attached around the side surface of the (spindle) hub 222 of the spindle motor 220 via their central perforation holes. The spacer 240 spaces the disks 230 and 250 by a constant distance corresponding to the thickness of the spacer 240. The disks 230 and 250 and the spacer 240 are an object be mounted and configured to rotate with the hub 222.

As shown in FIG. 1, the automatic mounting apparatus 100 arranges three stations 110A to 110C in a transportation direction C via a base plate 108 above a rack 106. Actually, as shown in FIG. 2, the glass or plastic case 101 is attached to the rack 106 and maintains the clean room environment.

The rack 106 has a rectangular parallelepiped shape and arranged on a floor F shown in FIG. 2 via a four holders 102 at four corners on the rectangular bottom surface and four casters 104 provided near the holders 102. A driving system and a control system are provided in the rack 106.

The station 110A receives a disk 230 from the disk cassette 180A mounted with a plurality of disks 230, and installs the lowest disk 230 as shown in FIG. 3. The station 110B receives a spacer 240 from a spacer cassette 180B mounted with a plurality of spacers 240, and mount the spacer 240 on the disk 230. The station 110C receives a disk 250 from the disk cassette 180C mounted with a plurality of disks 250, and mounts the highest disk 230 as shown in FIG. 3 on the spacer 240.

Each of the stations 110A to 110C includes an attachment mechanism 120, a centering unit 130, a robot arm 140, a robot arm driving mechanism 150, and a cassette holder 170. The automatic mounting apparatus 100 further includes a transportation mechanism 160 that extends in the transportation direction C and is commonly used for the stations 110A to 110C The transportation direction C is a direction parallel to one side of the rack 106 or the base plate 108 in this embodiment.

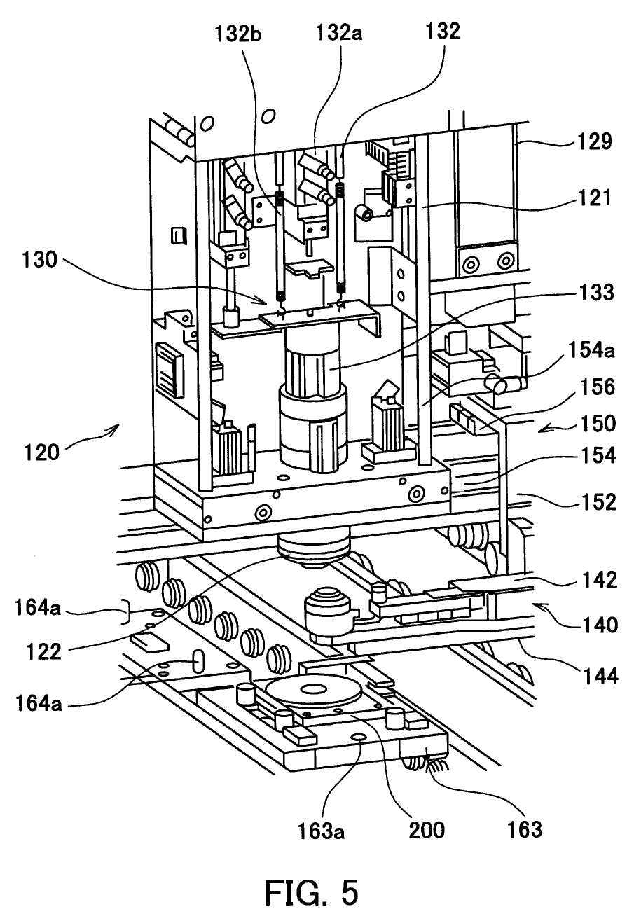

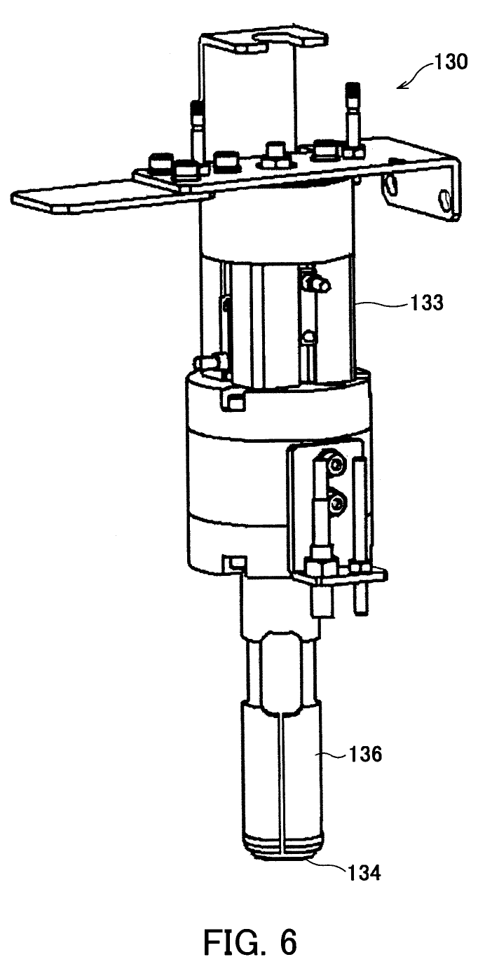

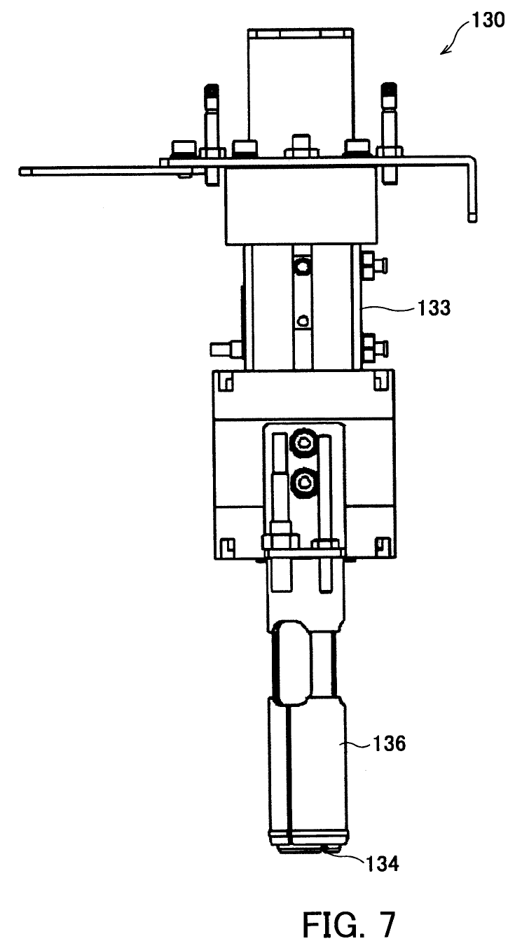

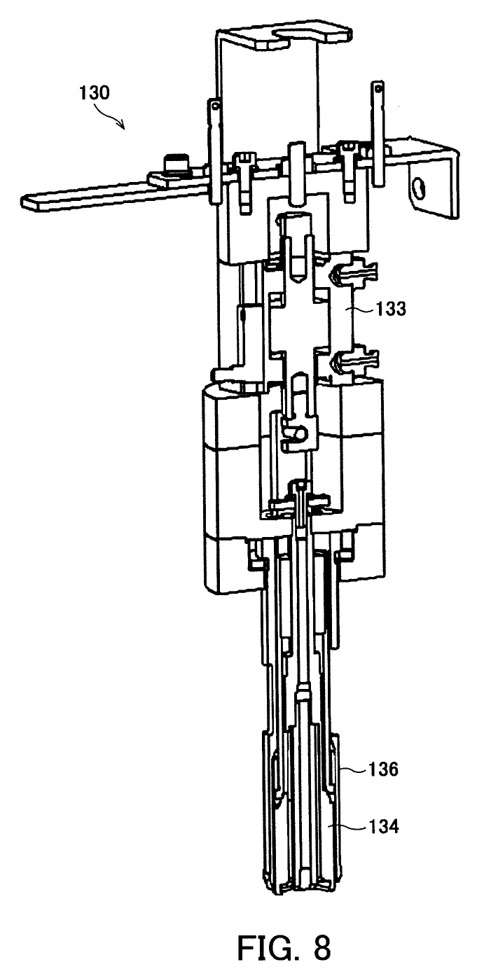

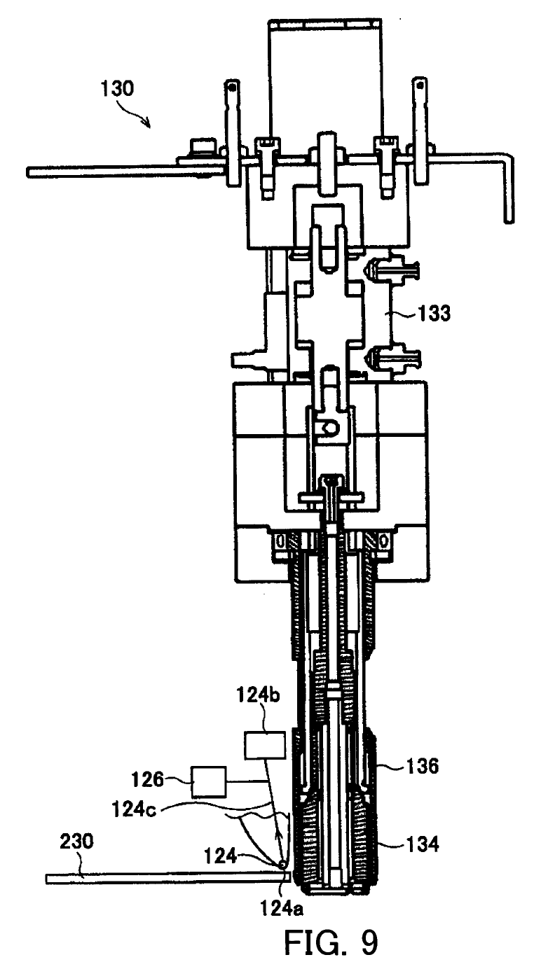

Referring now to FIGS. 5 to 9, a description will be given of the attachment mechanism 120, the centering unit 130, the robot arm 140, and the robot arm driving mechanism 150. Here, FIG. 5 is a partially enlarged, transparent and perspective view of the attachment mechanism 120. FIG. 6 is a partially enlarged perspective view of the centering unit 130. FIG. 7 is a partially enlarged plane view of the centering unit 130. FIG. 8 is a partially enlarged sectional and perspective view of the centering unit 130. FIG. 9 is a partially enlarged sectional view of the centering unit 130. FIGS. 6-8 show only the centering unit 130, and FIG. 9 schematically shows part of the attachment mechanism 120.

The attachment mechanism 120 mounts the object obtained from the robot arm 140 around the hub 222. At that time, the attachment mechanism 120 mounts the object while securing a predetermined clearance around the hub 222. The attachment mechanism 120 includes a body 121 and a moving mechanism 129.

The body 121 has an L shape, as shown in FIG. 1. The body 121 includes an upper arm 122, a suction unit 124, and a detector 126. The centering unit 130 is also installed in the body 121. As shown in FIG. 1, the inside of the body 121 cannot be seen from the outside, but FIG. 5 enlarges part of the body 121 in a transparent state.

The upper arm 122 has, as shown in FIG. 5, a dome or truncated cone shape, and projects vertically down from the body 121. The suction unit 124 is provided in the upper arm 122, and the object is held on the upper arm 122.

The suction unit 124 includes a suction port 124a, an exhaust unit 124b, and a channel 124c. The suction port 124a is provided at a part in the upper arm 122 so as to attract and hold a periphery of the center hole of the object, e.g., between a central perforation hole and an inner recording area on the disk 230. The suction port 124a is, but not limited to, an annular hole in this embodiment. For example, the suction port 124a may include a multiplicity of holes arranged in the circumferential direction at regular intervals. The exhaust unit 124b is connected to the suction port 124a via the channel 124c, and made, for example, of a vacuum pump.

The detector 126 is connected to the channel 124c between the suction port 124a and the exhaust unit 124b, and detects the pressure of the channel 124c.

The moving mechanism 129 includes, for example, a uniaxial robot and enables the body 121 to vertically move in the height direction H shown in FIG. 1. As long as the body 121 can vertically move in the H direction, the moving mechanism 129 may have another structure known in the art.

The centering unit 130 accords the center of the hub 222 with the center of the object, and maintains constant a clearance between the side surface of the hub 222 and the contour of the center hole of the object over the circumferential direction of the hub 222. In this state, the attachment mechanism 120 attaches the object around the hub 222. This configuration can prevent a contact between them during mounting or rubbing of the object against the side surface of the hub 222, and can restrain or eliminate the dust that would otherwise occur due to the frictions between them.

The centering unit 130 includes a moving mechanism 132, an opening/closing mechanism 133, an inner center unit 134, and an outer centering unit 136.

The moving mechanism 132 includes, for example, a uniaxial robot using an air cylinder 132a, and enables the centering unit 130 to vertically move in the height direction H shown in FIG. 1 relative to the body 121. As long as the centering unit 130 can vertically move in the H direction, the moving mechanism 132 may use any structures known in the art. The moving mechanism 132 reduces the driving force by using a pair of tension springs 132b.

The opening/closing mechanism 133 simultaneously opens and closes the inner centering unit 134 and the outer centering unit 136. When the inner centering unit 134 opens, it becomes wider than the inner cylinder 222b. Then, when the inner centering unit 134 closes, it can hold the inner cylinder 222b. On the other hand, when the outer centering unit 136 opens, it can fix the object. When the outer centering unit 136 closes, it can release the object. However, even when the outer centering unit 136 closes, if the suction unit 124 operates, the object remains to be held by the upper arm 122.

The inner centering unit 134 is a hollow cylindrical member that is engaged with the inner cylinder 222b and configured to center the hub 222. The outer centering unit 136 is a hollow cylindrical member that is provided concentrically to the inner centering unit 134, inserted into the center hole of the object, and configured to center the object. The centering unit 130 is implemented by a collet chuck. When the inner centering unit 134 that is the hollow cylindrical member is engaged with the inner cylinder 222b, their centers are aligned with each other. Since the outer centering unit 136 is concentric to the inner centering unit 134, their centers accord with each other. Moreover, when the outer centering unit 136 that is the hollow centering member is inserted into the center hole of the object, the center of the outer centering unit 136 accords with the center of the object. As a result, the center of the object can accord with the center of the inner cylinder 222b.

The robot arm 140 receives the object one by one from a corresponding cassette, transports it, and delivers it to the upper arm 122. The robot arm 140 includes, as shown in FIG. 5, an attachment unit 142, a base 144, and a lower arm 146.

The attachment unit 142 is provided at one end of the base 144, and fixed onto a drive plate 152 of the driving mechanism 150. The lower arm 146 is provided at the other end of the base 144. The lower arm 146 has, as shown in FIG. 5, a dome or truncated cone shape. The lower arm 146 has a suction unit having the same structure as the suction unit 124. The lower arm 146 is oriented to the vertically upper side. A controller 190 can control an exhaust action of the exhaust unit of the lower arm 146.

The robot arm driving mechanism 150 moves the robot arm 140 in the transportation direction C. The robot arm driving mechanism 150 includes an L-shape drive plate 152, a guide 154, and a slider 156. The attachment unit 142 is fixed onto a front surface of a vertical member of the drive plate 152, and the slider 156 is fixed onto a back surface of a horizontal member of the drive plate 152. The guide 154 has a rectangular parallelepiped shape, and extends in the transportation direction C. A rail 154a that is engaged with the slider 156 and configured to guide the slider 156 is provided on the top surface of the guide 154. The slider 156 is engaged with the rail 154a and moves in the transportation direction C along the rail 154a. When the rail 154a is configured as a ball screw and connected to the slider 156, the slider 156 can be moved along the rail 154a. As long as the robot arm 140 can be moved in the transportation direction C, the structure of the robot arm driving mechanism 150 may be replaced with another uniaxial robot.

The transportation mechanism 160 moves the DE 210 in the transportation direction C. More specifically, the transportation mechanism 160 transports the DE 210 in a C₁ direction along a transportation path 161a so as to mount the disk 230, the spacer 240, and the disk 250 onto the DE 210. Thereafter, it returns at the end (not shown), and transports the DE 210 along the transportation path 161b in the C₂ direction so as to return the DE 210 mounted with the object.

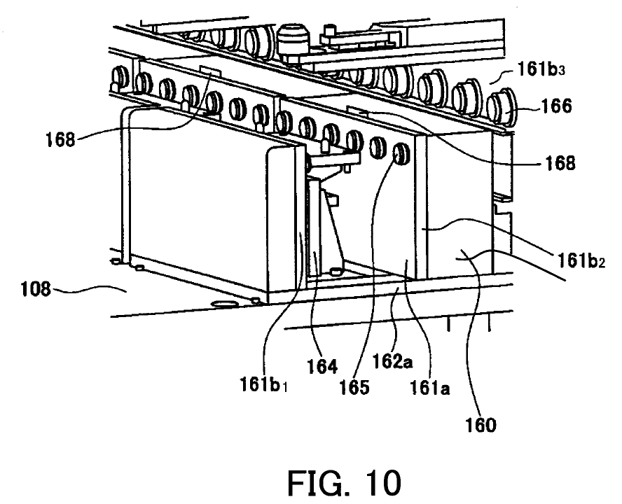

The transportation mechanism 160 includes, as shown in FIG. 10, a pair of transportation paths 161a and 161b, a bottom plate 162a, a pair of sidewalls 161b₁ and 161b₂ for the transportation path 161a, a plurality of rollers 165 for the transportation path 161a, and a plurality of detectors 168, a pair of side walls 161b₂ and 161b₃ for the transportation path 161b, a pallet 163, a plurality of engagement tables 164, and a plurality of rollers 166 for the transportation path 161b. The rollers 165 and 166 are driven by a plurality of motors 167, which are omitted in FIG. 10. Here, FIG. 10 is a partially enlarged perspective view of the transportation mechanism 160.

The bottom plate 162a is placed on the base plate 108. The pair of sidewalls 161b₁ and 161b₂ stand perpendicular to the bottom plate 162a so that the plurality of rollers 165 face each other at the same height and arranged at regular intervals along the transportation direction C. In addition, the pair of sidewalls 161b₂ and 161b₃ stand in the H direction so that the plurality of rollers 166 are opposed to each other at the same height and arranged at regular intervals along the transportation direction C. The left side surface of the sidewall 161b₂ shown in FIG. 10 is used for the transportation path 161a, and the right side surface of the sidewall 161b₂ is used for the transportation path 161b.

The pallet 163 is a rectangular parallelepiped table mounted with the DE 210 as shown in FIG. 5, and has a pair of front and back positioning holes 163a in the transportation direction C. The engagement table 164 can longitudinally move, support the pallet 163, and position the pallet 163 at the mounting position. The engagement table 164 is arranged at the mounting position of each station, as shown in FIG. 5, and has a pair of positioning pins 164a. Each positioning pin 164a is inserted into a corresponding positioning hole 163a of the pallet 163. As a result, the pallet 163 is positioned at the mounting position. The engagement table 164 is provided with a uniaxial robot that includes a motor, a guide, and an actuator, and its top table is configured to move up and down.

The plurality of rollers 165 and 166 are driven by a plurality of motors 167 and a driving mechanism that includes a belt (not shown). The rollers 165 and 166 contact part near both sides of the bottom surface of the pallet 163. Each roller 165 rotates so as to transport the pallet 163 in the C₁ direction, and each roller 166 rotates so as to transport the pallet 163 in the C₂ direction. Different motors 167 are used for the roller 165 and the roller 166. Usually, each roller 165 can be driven and stopped for each station, and each roller 166 is normally driven. Of course, a detector configured to detect whether there is a mounted DE 210 and the controller 190, which will be described later, may control the electrification to the motor 167 used to drive each roller 166.

The detector 168 detects whether the pallet 163 reaches the mounting position of each station. Each detector 168 may include, for example, a pair of transmission type optical sensors each including a light emitting element and a light receiving element, one of which is provided on the sidewall 161b₁ and the other of which is provided on the sidewall 161b₂. Each transmission type optical sensor is provided at a position corresponding one of both ends of the pallet 163 in the C direction which has reached the mounting position, and the detector 168 can detect that the pallet 163 reaches the mounting position when the light beams from the light emitting parts of both optical sensors are shielded.

The cassette holder 170 holds a pair of corresponding cassettes. The cassette holder 170 of the station 110A is mounted with a pair of disk cassettes 180A so that the disk cassette 180A can rotate and vertically move. Similarly, the cassette holder 170 of the station 110C is mounted with a pair of disk cassettes 180C so that the disk cassette 180C can rotate and vertically move.

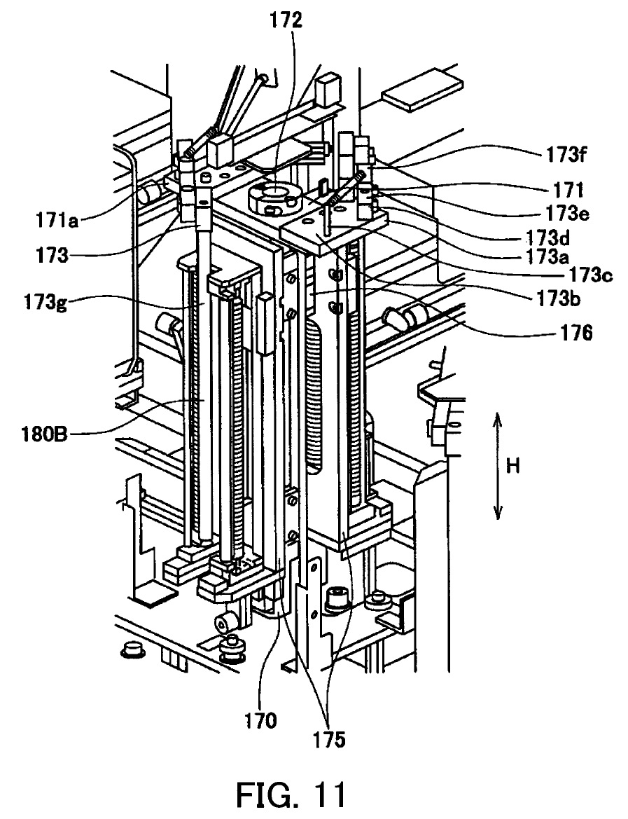

FIG. 11 is a partially enlarged perspective view showing the cassette holder 170 for the spacer cassettes 180B. As illustrated, the cassette holder 170 includes a body 171, a shaft 172, a press mechanism 173, a pair of mounting plates 175, and a pair of moving mechanisms 176.

The body 171 has an approximately rectangular parallelepiped shape, stands in the H direction, and rotates with the shaft 172 every 180°. The shaft 172 is coupled with a motor shaft of the motor 177, which is omitted in FIG. 11. The body 171 is provided with a transmission type optical sensor configured to form an optical path in the H direction. Even one object set in the cassette can shield the optical path by the object, but if there is no object the light passes and is received by the light receiving part. When there is no object, the controller 190, which will be described later, rotates the body 171 with the shaft 172.

The press mechanism 173 prevents the object from dropping out of the cassette during rotations, and includes a pair of top plates 173a, a plurality of screws 173b, a pair of pins 173c, a pair of bars 173d, a pair of pins 173e, a pair of tension springs 173f, and a pair of press rods 173g. Each top plate 173a is fixed onto an end of a top plate of the body 171 via the screws 173b. Each pin 173c stands in the H direction from the top plate 173a. Each bar 173d is rotatably fixed onto the top plate 173a at its one end via the pin 173e, and fixed onto the press rod 173g at the other end. In addition, it is connected to one end of each tension spring 173f between both ends. The other end of each tension spring 173f is connected to the pin 173c. The press rod 173g extends in the H direction. Since the tension spring 173f forces the bar 173d in the closing direction, the press rod 173g presses the object against the body 171.

The pair of mounting plates 175 are attached to a front surface (on the side opposite to the robot arm 140) and a back surface (opposite to the front surface). Each mounting plate 175 extends in the H direction, and holds the corresponding cassette.

Each moving mechanism 176 moves a corresponding mounting plate 175 in the H direction. The moving mechanism 176 is made of a uniaxial robot. The press rod 173g does not press the object at the lowest position, and exposes it. Thereby, the lower arm 146 can receive the object that is located at the lowest position. A reflection type optical sensor (not shown) that can form an optical path in a direction perpendicular to the H direction is attached to the body 171. Unless this optical sensor detects the object, the moving mechanism 176 moves the mounting plate 175 down along the H direction so as to expose the object at the lowest position from the press rod 173g.

The disk cassettes 180A and 180C have the same shape, and mount a plurality of disks in grooves that are arranged at regular intervals. Since the disk cassettes 180A and 180C do not have to be mounted in the cleansing apparatus, they have the same structure as the spacer cassette 180B except they do not expose the disks 230 and 250.

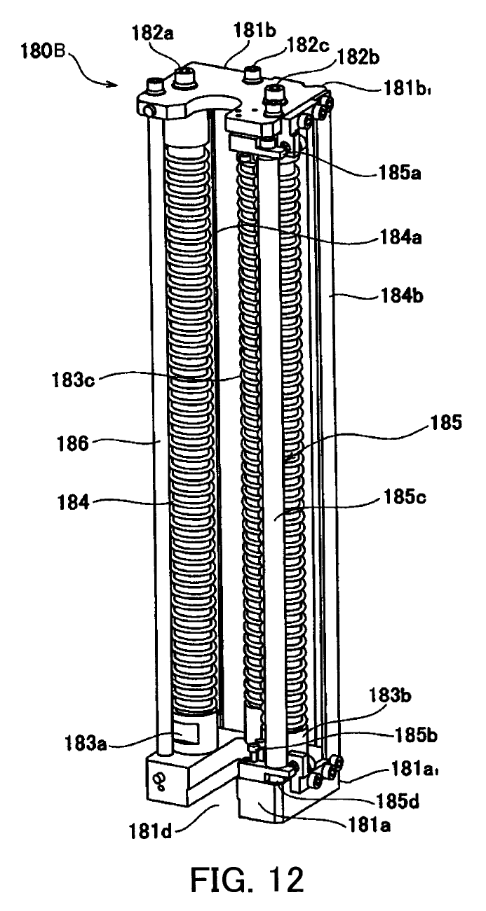

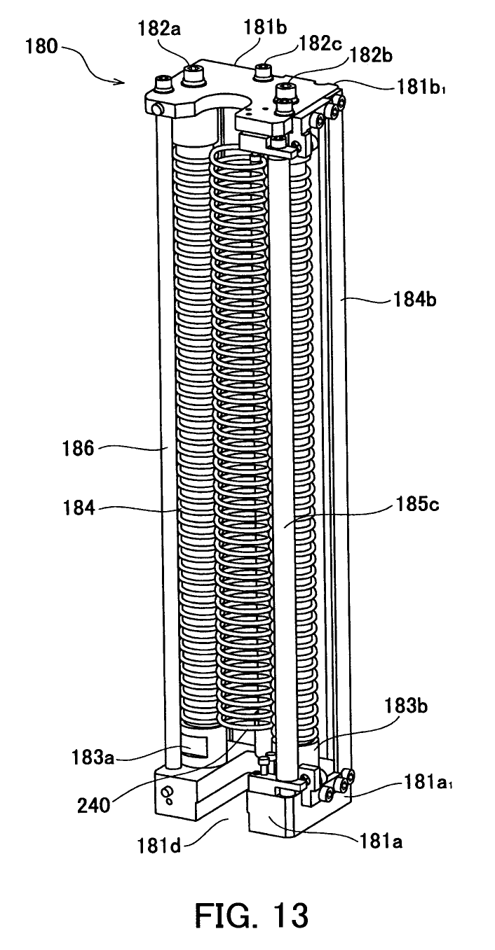

Referring now to FIGS. 11 to 13, a description will be given of the spacer cassette 180B. Here, FIG. 12 is an enlarged perspective view of the spacer cassette 180B that has no spacer 240. FIG. 13 is an enlarged perspective view of the spacer cassette 180B mounted with the spacer 240.

The spacer cassette 180B has a support configured to support the spacer 240 so that the spacer 240 can be taken out. The support exposes the spacer at part other than part that contacts the spacer 240. This configuration improves drainage in drying after cleansing. The spacer cassette 180B can be commonly mounted onto the automatic mounting apparatus 100 and the cleansing apparatus (not shown) configured to cleanse the spacer 240. As a result, the entire spacer cassette 180B can be cleansed. Since a transfer of the spacer 240 from the cleansing apparatus (not shown) to the cassette becomes unnecessary unlike the prior art, the dust that would otherwise occur due to the transfer can be restrained.

The spacer cassette 180B includes, as shown in FIG. 12, a pair of U-shaped fixture members 181a and 181b, bolts 182a to 182c, three cylinders 183a to 183c, a pair of grips 184a and 184b, a press mechanism 185, and a reinforcement pillow 186.

A pair of fixture members 181a and 181b serve as a top plate and a bottom plate of the spacer cassette 180B, and have the same shape. The fixture members 181a and 181b are arranged in parallel so that their U-shape concaves 181d face the same direction and are aligned with the H direction. The three cylinders 183a to 183c are provided between the pair of fixture members 181a and 181b, and fixed by the bolts 182a to 182c. A surface 181a₁ of the fixture member 181a and a surface 181b₁ of the fixture member 181b on the opposite side of the concave 181d are surfaces to be mounted onto the mounting plate 175.

The cylinders 183a to 183c have the same shape, and their centers form vertexes of the regular triangle when viewed from the top. However, the present invention does not limit the size and the arrangement of the cylinders 183a to 183c: For example, the cylinders 183a and 183b may have the same shape and the cylinder 183c may have a smaller diameter. The cylinders 183a to 183c have a multiplicity of circular grooves 184 that are arranged at regular intervals in the longitudinal direction (H direction). The spacer 240 is inserted into each cylindrical groove 184, as shown in FIG. 13. Thus, the three cylinders 183a to 183c serve as a support member of the spacer 240.

The grips 184a and 184b are rectangular parallelepiped bars used for an operator to hold the cassette 180B. The present invention does not limit a shape and a position of each of the grips 184a and 184b, but an arrangement of the grips 184a and 184b distant from the cylinders 183a to 183c can prevent the operator from adhering the dust to the spacer 240.

The pressure mechanism 185 prevents the spacers 240 from dropping out of the cassette 180B due to the vibrations of the spacer 240 in the ultrasonic cleansing, and includes a pair of bars 185a, a pair of pins 185b, a pressure rod 185c, and a pair of bolts 185d. Each bar 185a is rotatably fixed onto the fixture member 181a or 181b via the pin 185b, and its other end is fixed onto the press rod 185c via the bolt 185d. The press rod 185c extends in the H direction parallel to the cylinders 183a to 183c. In cleansing, the operator rotates a pair of bars 185a around the pin 185b from the state shown in FIG. 12 by 180°. Thereby, the press rod 185c is inserted into the concave 181d and compresses the spacer 240. After cleansing, the operator rotates the pair of bars 185a around the pins 185b in the reverse direction by 180° by the reverse operation to return the press mechanism 185 to the state shown in FIG. 12. This structure can hold the adjacent spacers 240 without collisions during cleansing, such as at the ultrasonic cleansing time. The spacer cassette 180B is made of a durable material, such as stainless steel.

The reinforcement pillar 186 reinforces the spacer cassette 180B.

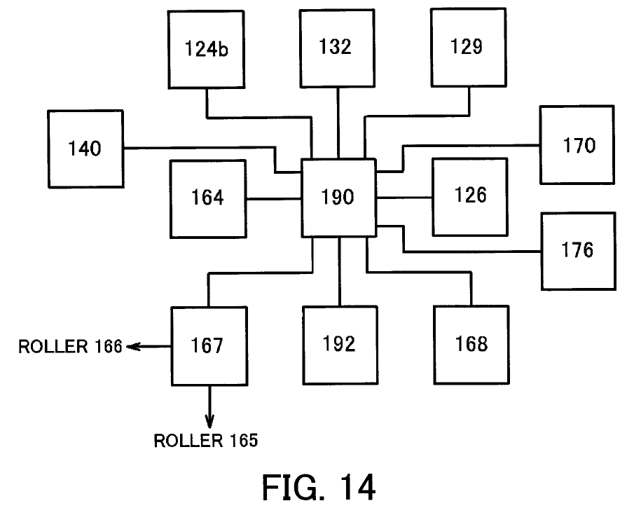

FIG. 14 is a block diagram for explaining a control system of the automatic mounting apparatus 100. The control system includes the controller 190 and a memory 192. The controller 190 is connected to the memory 192 and the detectors 126 and 168, and controls each part of the automatic mounting apparatus 100 based on the detection results of the detectors.

The controller 190 determines whether the object is attracted to the suction port 124a based on the detection result of the detector 126, or controls the exhaust action by the exhaust unit 124b. In this case, the controller 190 determines whether the object is attracted to the suction port 124a based on a pressure difference between the state in which the object is attracted to the suction port 124a and the state in which the object is not attracted. In addition, the controller 190 stops attractions by the exhaust unit 124b, and allows the object to drop around the hub 222. The controller 190 can recognize vertical moving amounts of the moving mechanisms 129, 132, and 176 and the moving amount of the robot arm 140 by the robot arm driving mechanism 150 based on encoders (not shown) and other detectors. The controller 190 moves up and down the engagement table 164 based on the detection result of the detector 168. The controller 190 rotates the body 171 of the cassette holder 170 when the cassette runs short of objects. The controller 190 drives the moving mechanism 176 in accordance with a positional relationship between the object and the lower arm 146. Thereby, the object can be delivered to the lower arm 144.

The memory 192 stores a variety of data necessary for the operations of the controller 190.

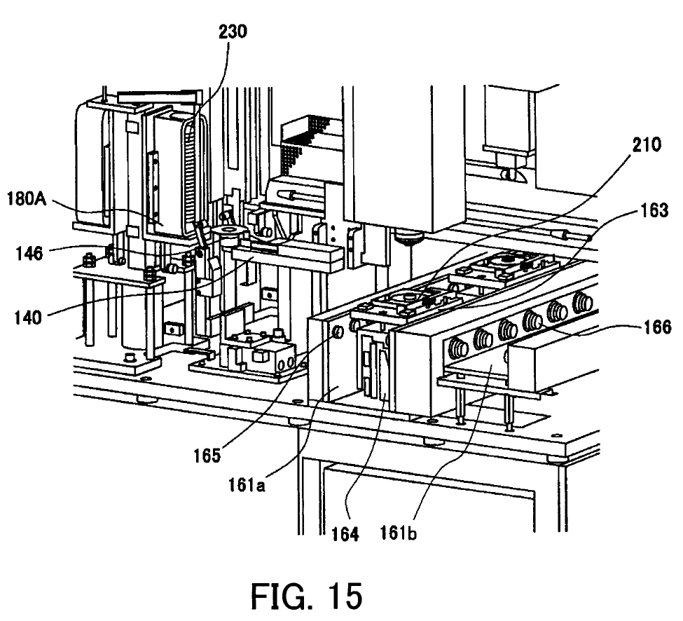

Referring now FIGS. 15-24, a description will be given of an operation of the automatic mounting apparatus 100.

Initially, as shown in FIG. 15, the lower arm 146 of the robot arm 140 in the station 110A takes the disk 230 at the lowest position in the disk cassette 180A through attractions. The controller 190 can recognize, based on the detection result of the detector corresponding to the detector 126 of the lower arm 146, whether the disk 230 is attracted by the lower arm 146. Then, the controller 190 controls the robot arm driving mechanism 150 so as to move the robot arm 140 in the C₂ direction.

Simultaneously and in parallel, the controller 190 transports the pallet 163 mounted with the DE 210 along the transportation path 161a by controlling the motor 167 and by rotating the rollers 165. When the pallet 163 is transported to the mounting position by the rollers 165 and detected by the detector 168, the controller 190 stops driving the motor 167. As a result, the subsequent HDD 200 does not become in a free flow state, and the dust generation due to the frictions can be prevented.

Next, the controller 190 moves up the engagement table 164. As a result, the positioning pins 164a of the engagement table 164 are inserted into the positioning holes 163a in the pallet 163 and positioning is completed. In FIGS. 15-24, the positioning pins 164a are not inserted into the positioning pins 163a for illustration convenience.

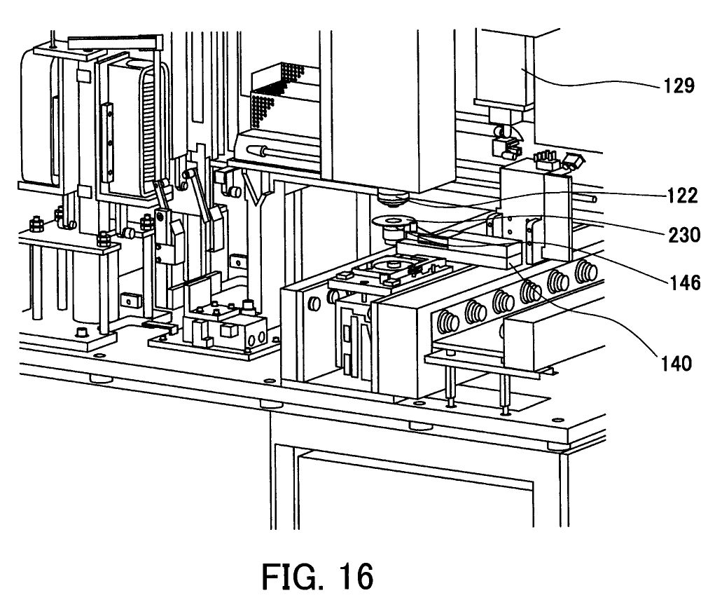

Next, as shown in FIG. 16, the lower arm 146 of the robot arm 140 moves right under the upper arm 122. The controller 190 can recognize whether the lower arm 146 has moved to this position, through a communication with the robot arm driving mechanism 150.

Initially, in this state, the inner centering unit 134 and the outer centering unit 136 of the centering unit 130 project from the bottom of the upper arm 122. In addition, the opening/closing mechanism 133 closes the inner centering unit 134 and the outer centering unit 136. Next, the controller 190 controls the moving mechanism 132, and moves the centering unit 130 up along the direction H relative to the upper arm 122. As a result, the upper arm 122 opposes to the lower arm 146 while the inner centering unit 134 and the outer centering unit 136 have retreated to the inside of the upper arm 122.

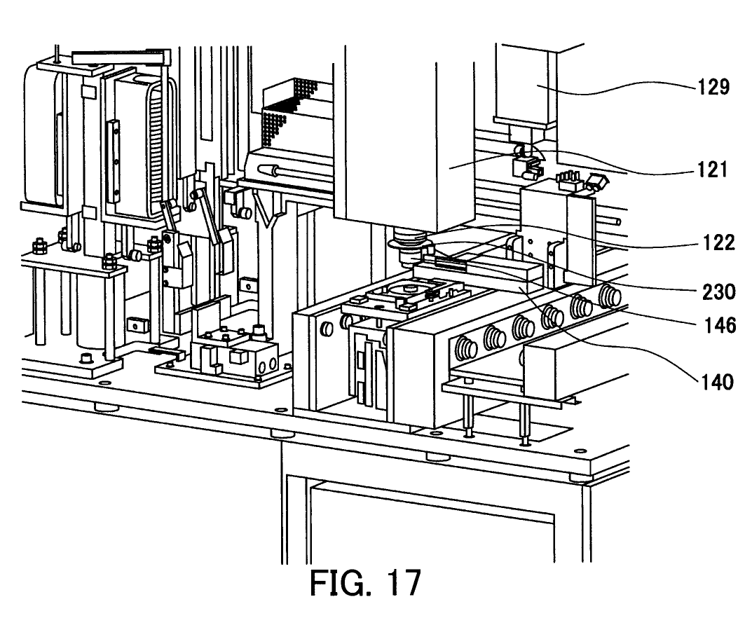

Next, the controller 190 moves the body 121 down along the H direction via the moving mechanism 129. As a result, the upper arm 122 becomes closer to the lower arm 146. Thereafter, the controller 190 stops descending the body 121. FIG. 17 shows this state. In this state, the controller 190 drives the exhaust unit 126 of the upper arm 122 and stops the exhaust unit of the lower arm 146. As a result, the disk 230 is attracted by the upper arm 122.

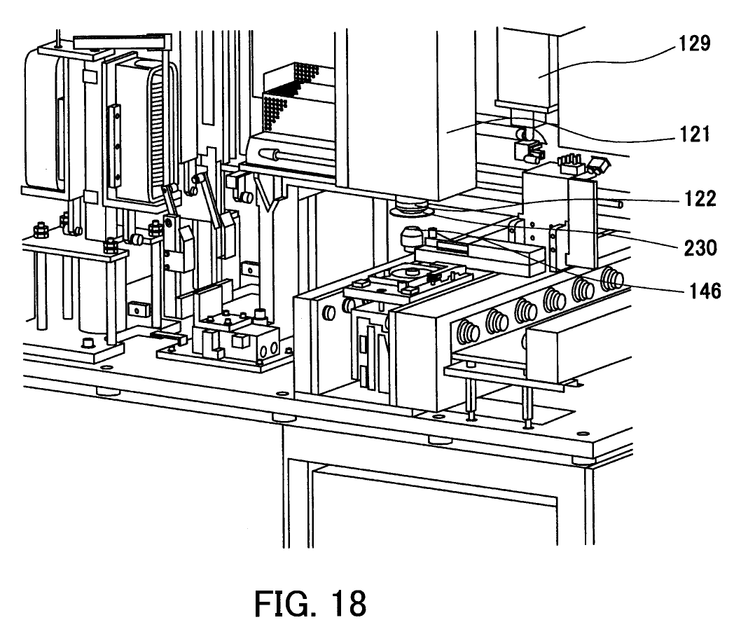

Next, the controller 190 moves the body 121 up along the H direction via the moving mechanism 129. As a result, the upper arm 122 is separated from the lower arm 146. Thereafter, the controller 190 stops ascending the body 121. FIG. 18 shows this state.

In this state, the center of the disk 230 does not accord with the center of the hub 222. Accordingly, the controller 190 next controls the moving mechanism 132 to move the centering unit 130 down in the H direction relative to the upper arm 122. As a result, the inner centering unit 134 and the outer centering unit 136 project from the bottom of the upper arm 122. The disk 230 is attached outside of the outer centering unit 136. Next, the controller 190 opens the inner centering unit 134 and the outer centering unit 136 via the opening/closing mechanism 133. Thereby, the inner centering unit 134 can be engaged with the inner cylinder 222b, and the outer centering unit 136 enables the center of the disk 230 to accord with the center of the outer centering unit 136.

Next, the controller 190 moves the body 121 down in the H direction via the body 121. As a result, the inner centering unit 134 grasps the inner cylinder 222b of the hub 222. Next, the controller 190 closes the inner centering unit 134 and the outer centering unit 136 via the opening/closing mechanism 133. Thereby, the inner centering unit 134 is strongly engaged with the inner cylinder 222b. As a result, the centers of the inner centering unit 134 and the inner cylinder 222b accord with each other. Even when the outer centering unit 136 closes, the disk 230 is held by the suction unit 124 on the upper arm 122.

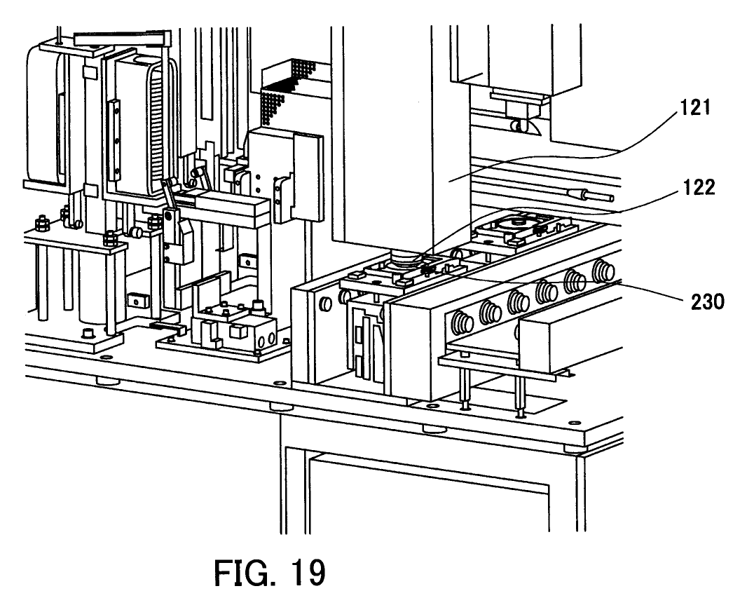

Next, the controller 190 further moves the body 121 down in the H direction via the moving mechanism 129 while fixing the position of the centering unit 130 via the moving mechanism 132. As a result, while the position of the centering unit 130 is fixed, the upper arm 122 and the disk 230 held by the upper arm 122 move down together. FIG. 19 shows this state.

Since the center of the hub 222 accords with the center of the disk 230, the clearance between the side surface of the hub 222 and the contour of the center hole of the disk 230 is maintained constant over the circumferential direction of the hub 222. In this state, the attachment mechanism 120 attaches the disk 230 to the circumference of the hub 222. This configuration can prevent a contact between them during mounting or restrain rubbing of the disk 230 against the side surface of the hub 222, thereby reducing generations of the dusts that would otherwise occur due to the frictions between them.

While the disk 230 is almost placed on the hub 222, the controller 190 stops exhaustions of the exhaust unit 126, and the disk 230 naturally drops around the hub 222. Thereby, mounting of the disk 230 is completed.

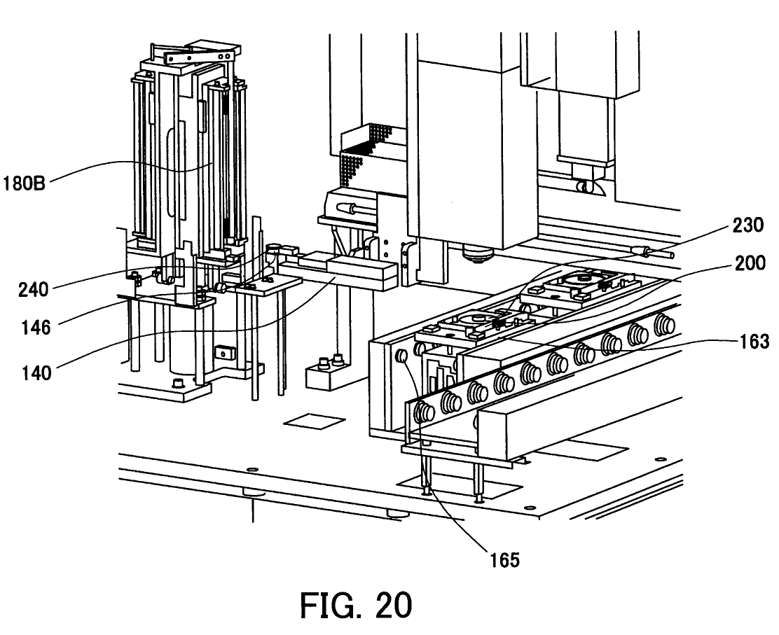

Thereafter, the controller 190 moves the body 121 up in the H direction via the moving mechanism 129. In addition, the controller 190 controls the motor 167 to rotate the rollers 165 to transport the pallet 163 to the mounting position of the station 110B. FIG. 20 shows this state. In addition, in this state, the lower arm 146 of the robot arm 140 in the station 110B takes the spacer 240 at the lowest position in the spacer cassette 180B.

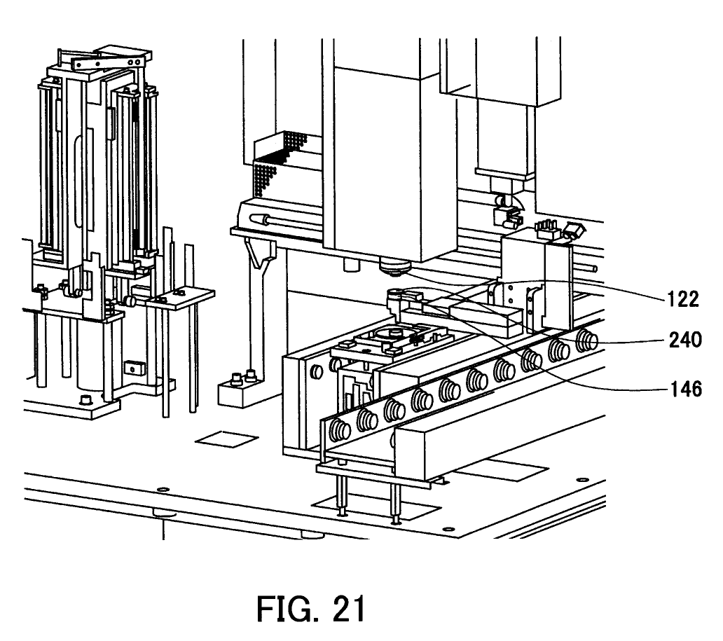

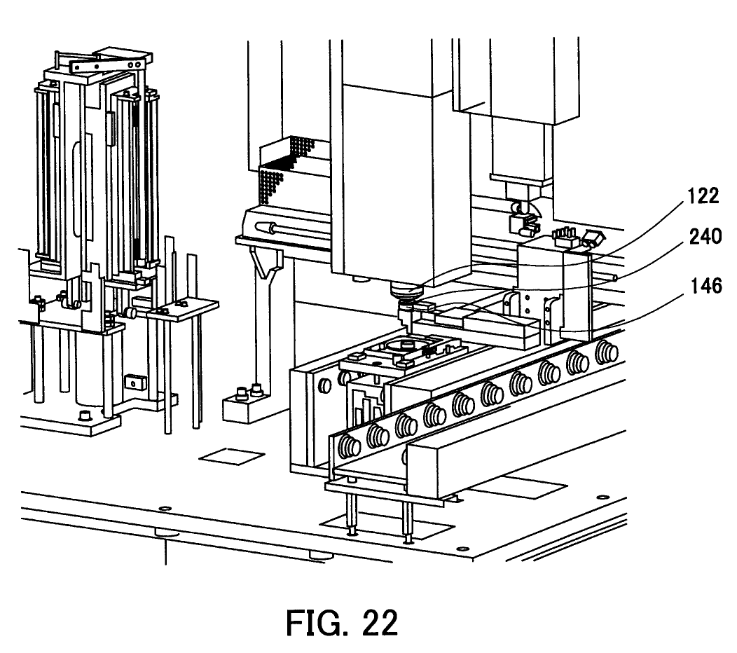

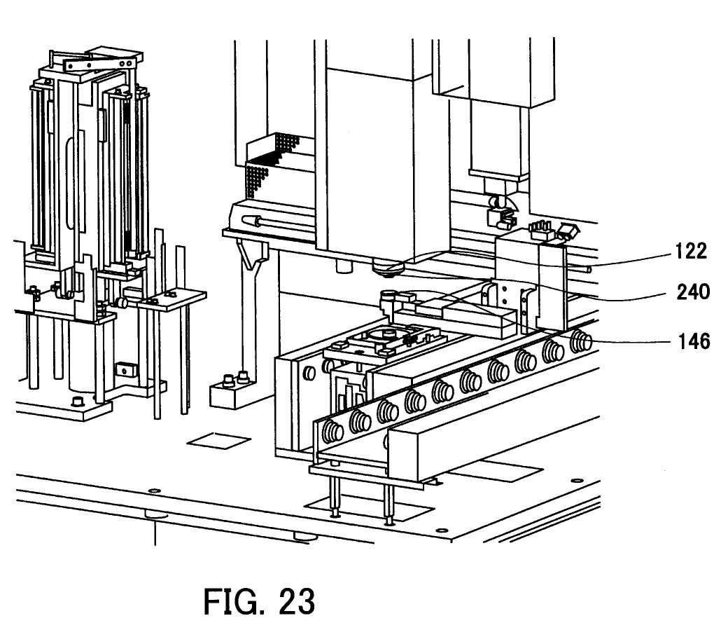

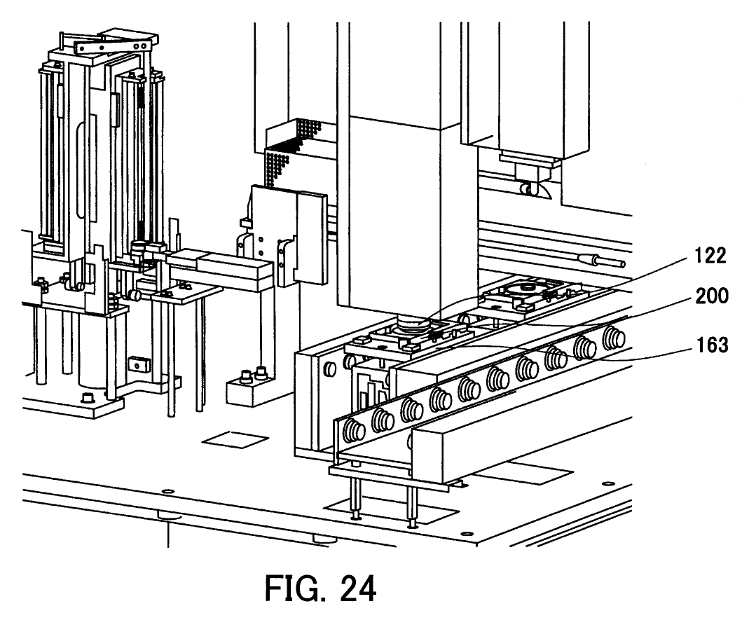

The attachment of the spacer 240 is similar to the attachment of the disk 230, and thus a description thereof will be omitted. FIG. 21 corresponds to FIG. 16, and is a perspective view showing that the lower arm 146 has moved right under the upper arm 122. FIG. 22 corresponds to FIG. 17, and is a perspective view showing that the upper arm 122 becomes close to the lower arm 146. FIG. 23 corresponds to FIG. 18, and is a perspective view showing that the upper arm 122 is distant from the lower arm 146 after the spacer 240 is delivered to the upper arm 122. FIG. 24 corresponds to FIG. 19, and is a perspective view showing that the attachment mechanism 120 attaches the spacer 240 while the center of the spacer 240 accords with the center of the hub 222.

This embodiment mounts one object at one position rather than mounting all objects onto the HDDs 200 at one point. This parallel processing can enhance the productivity.

Further, the invention is not limited to the disclosed exemplary embodiments, and various modifications and variations may be made.

The present invention can provide a manufacturing apparatus configured to manufacture a highly dustproof disk drive with good productivity.

What is claimed is:

1. A manufacturing apparatus configured to manufacture a storage unit by mounting an object onto a spindle motor that is attached to a housing and configured to rotate the object, said manufacturing apparatus comprising:
a centering mechanism that includes a first centering unit configured to be engaged with a spindle hub of the spindle motor and to center the spindle hub, and a second centering unit provided concentric to the first centering part and configured to center the object; and
an attachment unit configured to attach the object around the spindle hub while said centering mechanism accords a center of the spindle hub with a center of the object.

2. The manufacturing apparatus according to claim 1, wherein the object includes at least two disks each serving as a recording medium, and a spacer provided between the disks and configured to space the disks, and
wherein the manufacturing apparatus includes at least three centering mechanisms and at least three attachment units corresponding to the two disks and the spacer.

3. The manufacturing apparatus according to claim 2, further comprising three stations arranged at different positions in parallel,
wherein each station includes a pair of corresponding centering mechanism and attachment unit, and a moving unit configured to move the housing and to stop the housing when the housing is located at a mounting position.

4. The manufacturing apparatus according to claim 2, further comprising a spacer cassette that includes a support configured to support the spacer so that the spacer can be taken out, the spacer cassette exposing the spacer at part other than part at which the support contacts the spacer, and the spacer cassette being configured to commonly mounted on the manufacturing apparatus and a cleansing apparatus configured to cleanse the spacer.

5. The manufacturing apparatus according to claim 4, wherein the support includes three cylinders used to hold the spacer, each cylinder having a plurality of annular grooves arranged at regular intervals in a longitudinal direction, the spacer being engaged with each annular groove.
